(19) United States
(12) Patent Application Publication
(10) Pub. No.: US 2022/0293617 A1
(43) Pub. Date: Sep. 15, 2022

(54) SEMICONDUCTOR STORAGE DEVICE

(71) Applicant: Kioxia Corporation, Tokyo (JP)

(72) Inventor: Hirotaka TSUDA, Yokkaichi Mie (JP)

(73) Assignee: Kioxia Corporation, Tokyo (JP)

(21) Appl. No.: 17/462,283

(22) Filed: Aug. 31, 2021

(30) Foreign Application Priority Data
Mar. 9, 2021 (JP) 2021-037430

(51) Int. Cl. H01L 27/11524; H01L 27/11519; H01L 27/11565; H01L 27/1157

(52) U.S. Cl. CPC H01L 27/11524; H01L 27/11519; H01L 27/11565; H01L 27/1157

(57) ABSTRACT

A semiconductor storage device includes a first conductive layer extending in a first direction; a second conductive layer arranged apart from the first conductive layer in a second direction intersecting the first direction, and extending in the first direction; a plurality of semiconductor layers provided between the first conductive layer and the second conductive layer, arranged in the first direction, and including a first region facing the first conductive layer, a second region facing the second conductive layer, a third region connected to one end of the first region in the first direction and one end of the second region in the first direction, and a fourth region connected to the other end of the first region in the first direction and the other end of the second region in the first direction; a plurality of first memory cells provided between the first conductive layer and the plurality of semiconductor layers, respectively; and a plurality of second memory cells provided between the second conductive layer and the plurality of semiconductor layers, respectively. A gap is provided between two semiconductor layers adjacent to each other in the first direction.

### CROSS-REFERENCE TO RELATED APPLICATION

This application is based upon and claims the benefit of priority from Japanese Patent Application No. 2021-037430, filed Mar. 9, 2021, the entire contents of which are incorporated herein by reference.

### FIELD

Embodiments described herein relate generally to a semiconductor storage device.

### BACKGROUND

A semiconductor storage device is known that includes a substrate, a plurality of gate electrodes stacked in a direction intersecting the surface of the substrate, a semiconductor layer facing the plurality of gate electrodes, and a gate insulating layer provided between the gate electrode and the semiconductor layer. The gate insulating layer includes a memory unit capable of storing data, such as an insulating charge storage unit such as silicon nitride (SiN), and a conductive charge storage unit such as a floating gate.

### DESCRIPTION OF THE DRAWINGS

FIG. 1 is a schematic equivalent circuit diagram of a semiconductor storage device according to a first embodiment.

FIG. 2 is a schematic plan view of the semiconductor storage device.

FIG. 3 is a schematic cross-sectional view of the semiconductor storage device.

FIG. 4 is a schematic cross-sectional view of the semiconductor storage device.

FIG. 5 is a schematic cross-sectional view of the semiconductor storage device.

FIG. 6 is a schematic cross-sectional view of the semiconductor storage device.

FIG. 7 is a schematic cross-sectional view showing a manufacturing method of the semiconductor storage device.

FIG. 8 is a schematic cross-sectional view showing the manufacturing method.

FIG. 9 is a schematic cross-sectional view showing the manufacturing method.

FIG. 10 is a schematic cross-sectional view showing the manufacturing method.

FIG. 11 is a schematic cross-sectional view showing the manufacturing method.

FIG. 12 is a schematic cross-sectional view showing the manufacturing method.

FIG. 13 is a schematic cross-sectional view showing the manufacturing method.

FIG. 14 is a schematic cross-sectional view showing the manufacturing method.

FIG. 15 is a schematic cross-sectional view showing the manufacturing method.

FIG. 16 is a schematic cross-sectional view showing the manufacturing method.

FIG. 17 is a schematic cross-sectional view showing the manufacturing method.

FIG. 18 is a schematic cross-sectional view showing the manufacturing method.

FIG. 19 is a schematic cross-sectional view showing the manufacturing method.

FIG. 20 is a schematic cross-sectional view showing the manufacturing method.

FIG. 21 is a schematic cross-sectional view showing the manufacturing method.

FIG. 22 is a schematic cross-sectional view showing the manufacturing method.

FIG. 23 is a schematic cross-sectional view showing the manufacturing method.

FIG. 24 is a schematic cross-sectional view showing the manufacturing method;

FIG. 25 is a schematic cross-sectional view showing the manufacturing method.

FIG. 26 is a schematic cross-sectional view showing the manufacturing method.

FIG. 27 is a schematic cross-sectional view showing the manufacturing method.

FIG. 28 is a schematic cross-sectional view showing the manufacturing method.

FIG. 29 is a schematic cross-sectional view showing the manufacturing method.

FIG. 30 is a schematic cross-sectional view showing the manufacturing method.

FIG. 31 is a schematic cross-sectional view showing the manufacturing method.

FIG. 32 is a schematic cross-sectional view showing the manufacturing method.

FIG. 33 is a schematic cross-sectional view showing the manufacturing method.

FIG. 34 is a schematic cross-sectional view showing the manufacturing method.

FIG. 35 is a schematic cross-sectional view showing the manufacturing method.

FIG. 36 is a schematic cross-sectional view showing the manufacturing method.

FIG. 37 is a schematic cross-sectional view showing the manufacturing method.

FIG. 38 is a schematic cross-sectional view illustrating the read operation according to the first embodiment.

FIG. 39 is a schematic cross-sectional view illustrating the write operation according to the first embodiment.

FIG. 40 is a schematic cross-sectional view of a semiconductor storage device according to a comparative example.

FIG. 41 is a schematic cross-sectional view of a semiconductor storage device according to a second embodiment.

FIG. 42 is a schematic cross-sectional view of the semiconductor storage device.

FIG. 43 is a schematic cross-sectional view of the semiconductor storage device.

FIG. 44 is a schematic cross-sectional view showing a manufacturing method of the semiconductor storage device.

FIG. 45 is a schematic cross-sectional view showing the manufacturing method.

FIG. 46 is a schematic cross-sectional view showing the manufacturing method.

FIG. 47 is a schematic cross-sectional view showing the manufacturing method.

FIG. 48 is a schematic plan view showing the manufacturing method.

FIG. 49 is a schematic plan view showing the manufacturing method;

FIG. 50 is a schematic cross-sectional view showing the manufacturing method.

FIG. 51 is a schematic cross-sectional view showing the manufacturing method.

FIG. 52 is a schematic cross-sectional view showing the manufacturing method.

### DETAILED DESCRIPTION

At least one embodiment provides a semiconductor storage device capable of high integration.

In general, according to at least one embodiment, a semiconductor storage device includes a first conductive layer extending in a first direction; a second conductive layer arranged apart from the first conductive layer in a second direction intersecting the first direction, and extending in the first direction; a plurality of semiconductor layers provided between the first conductive layer and the second conductive layer, arranged in the first direction, and including a first region facing the first conductive layer, a second region facing the second conductive layer, a third region connected to one end of the first region in the first direction and one end of the second region in the first direction, and a fourth region connected to the other end of the first region in the first direction and the other end of the second region in the first direction; a plurality of first memory cells provided between the first conductive layer and the plurality of semiconductor layers, respectively; and a plurality of second memory cells provided between the second conductive layer and the plurality of semiconductor layers, respectively. A gap is provided between two semiconductor layers adjacent to each other in the first direction.

Next, the semiconductor storage devices according to the embodiments will be described in detail with reference to the drawings. The following embodiments are merely examples and are not intended to limit the present disclosure. In addition, the following drawings are schematic and some configurations and the like may be omitted for convenience of explanation. In addition, the same reference numerals are given to the parts common in the plurality of embodiments, and the descriptions thereof may be omitted.

Further, when the term “semiconductor storage device” is used in the present specification, the term may mean a memory die, or a memory system including a control die such as a memory chip, a memory card, or a solid state drive (SSD). Further, the term may mean a configuration including a host computer such as a smartphone, a tablet terminal, and a personal computer.

Further, in the present specification, when a first configuration is said to be “electrically connected” to a second configuration, the first configuration may be directly connected to the second configuration, or the first configuration may be connected to the second configuration via wiring, a semiconductor member, a transistor, or the like. For example, when three transistors are connected in series, the first transistor is “electrically connected” to the third transistor, even if the second transistor is in the OFF state.

Further, in the present specification, when the first configuration is said to be “connected between” the second configuration and a third configuration, it may mean that the first configuration, the second configuration, and the third configuration are connected in series and that the second configuration is connected to the third configuration via the first configuration.

Further, in the present specification, a predetermined direction parallel to the upper surface of the substrate is referred to as an X direction, a direction parallel to the upper surface of the substrate and perpendicular to the X direction is referred to as a Y direction, and a direction perpendicular to the upper surface of the substrate is referred to as a Z direction.

Further, in the present specification, a direction along the predetermined surface may be referred to as a first direction, a direction intersecting the first direction along the predetermined surface may be referred to as a second direction, and a direction intersecting the predetermined surface may be referred to as a third direction. The first direction, the second direction, and the third direction may or may not correspond to any of the X direction, the Y direction, and the Z direction.

Further, in the present specification, expressions such as “upper” and “lower” are based on the substrate. For example, a direction away from the substrate along the Z direction is referred to as upward, and a direction approaching the substrate along the Z direction is referred to as downward. Further, when referring to a lower surface or a lower end of a certain configuration, it means a surface or an end portion on the substrate side of the configuration, and when referring to an upper surface or an upper end, it means a surface or an end portion on the opposite side of the substrate of the configuration. Further, a surface that intersects the X direction or the Y direction is referred to as a side surface or the like.

### First Embodiment

[Configuration]

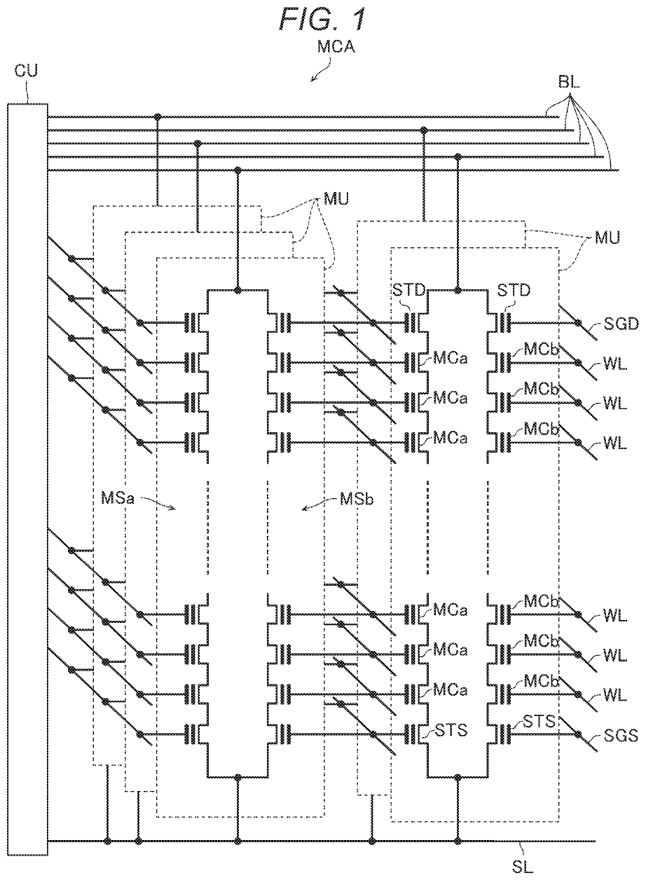

FIG. 1 is a schematic equivalent circuit diagram of a semiconductor storage device according to a first embodiment.

The semiconductor storage device according to the present embodiment includes a memory cell array MCA and a control unit CU that controls the memory cell array MCA.

The memory cell array MCA includes a plurality of memory units MU. Each of the plurality of memory units MU includes two electrically independent memory strings MSa and MSb. One end of each of the memory strings MSa and MSb is connected to a drain-side select transistor STD and is connected to a common bit line BL via the drain-side select transistor STD. The other end of each of the memory strings MSa and MSb is connected to a source-side select transistor STS and is connected to a common source line SL via the source-side select transistor STS.

Each of the memory strings MSa and MSb includes a plurality of memory cells MCa and a plurality of memory cells MCb connected in series. The memory cell MCa and the memory cell MCb are field effect transistors including a semiconductor layer, a gate insulating layer, and a gate electrode. The semiconductor layer functions as a channel region. The gate insulating layer includes a charge storage unit that can store data. The threshold voltages of the memory cell MCa and the memory cell MCb change according to the amount of charge in the charge storage unit. The gate electrode is a part of a word line WL. Hereinafter, when there is no distinction, the memory cell MCa and the memory cell MCb may be simply referred to as a memory cell MC.

The select transistor (STD and STS) may be a field effect transistor including a semiconductor layer, a gate insulating layer, and a gate electrode. The semiconductor layer functions as a channel region. The gate electrode of the drain-side select transistor STD is a part of a drain-side select gate line SGD. The gate electrode of the source-side select transistor STS is a part of a source-side select gate line SGS.

The control unit CU generates, for example, a voltage required for the read operation, a write operation, and an erasing operation, and supplies the voltage to the bit line BL, the source line SL, the word line WL, and the select gate line (SGD and SGS). The control unit CU may include, for example, a plurality of transistors and wirings provided on the same substrate as the memory cell array MCA, or may include a plurality of transistors and wirings provided on a substrate different from the memory cell array MCA.

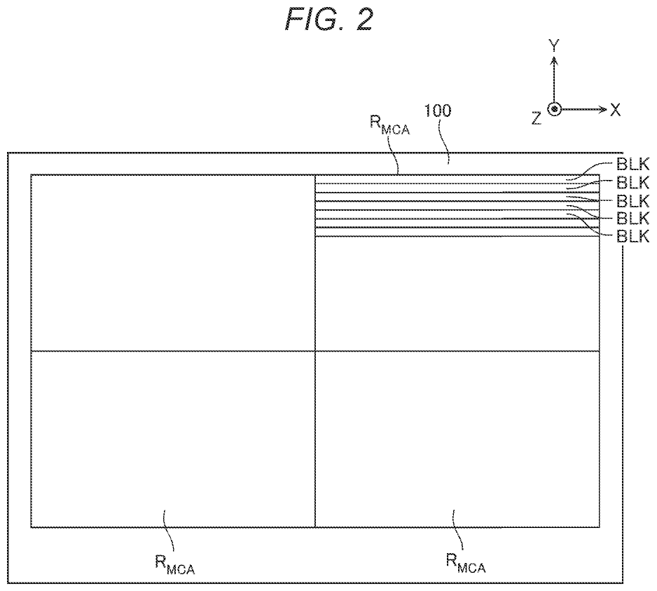

FIG. 2 is a schematic plan view showing a configuration example of the semiconductor storage device according to at least one embodiment.

The semiconductor storage device according to at least one embodiment includes a semiconductor substrate 100. In the illustrated example, the semiconductor substrate 100 is provided with four memory cell array regions R_{MCA} arranged in the X direction and the Y direction. Each memory cell array region R_{MCA} is provided with a plurality of memory blocks BLK arranged in the Y direction. Each memory block BLK extends in the X direction.

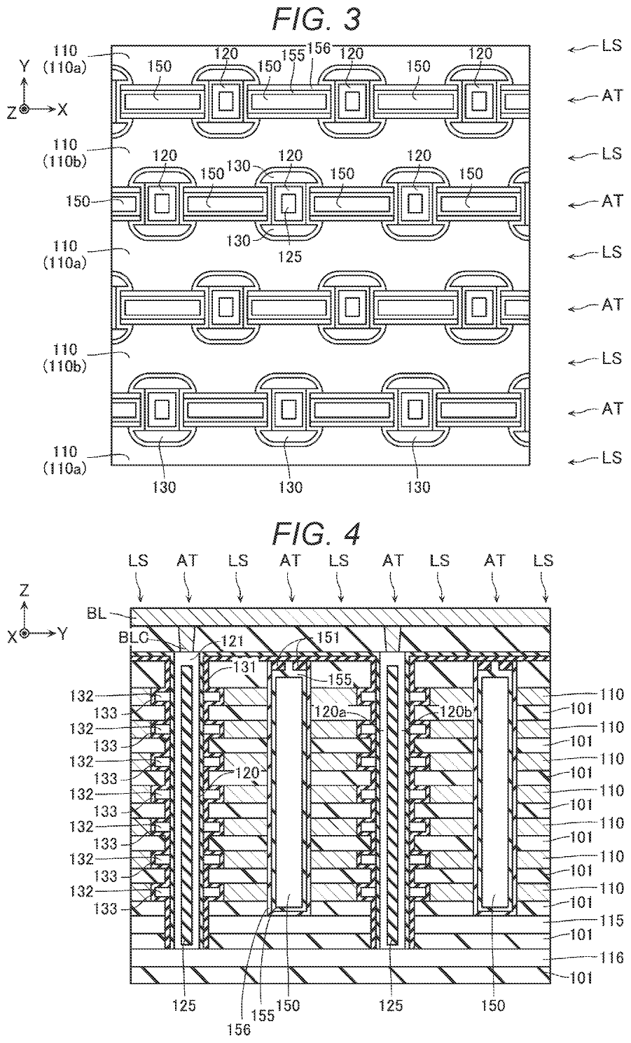

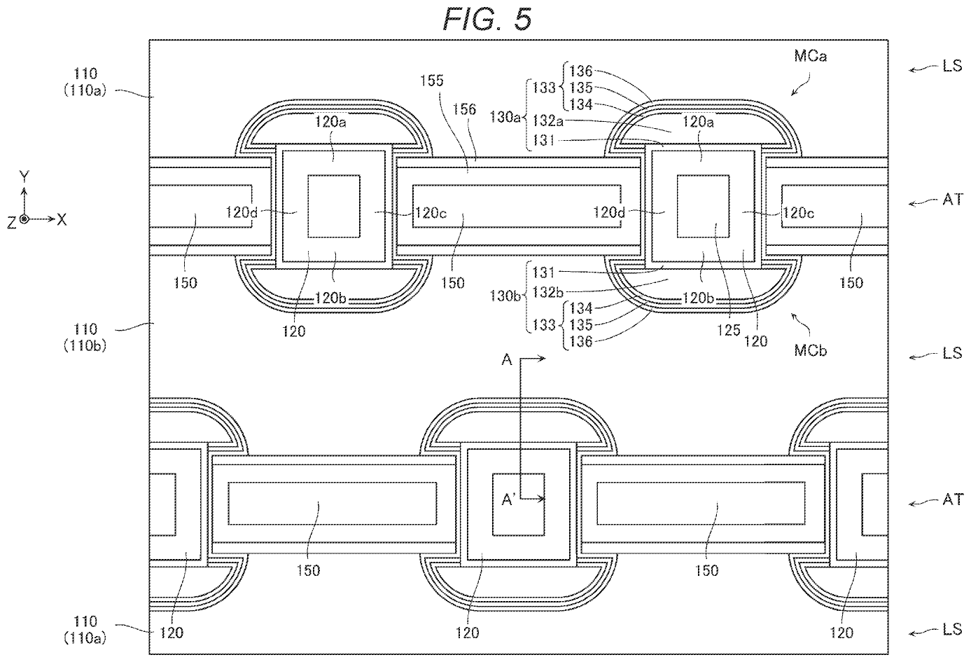

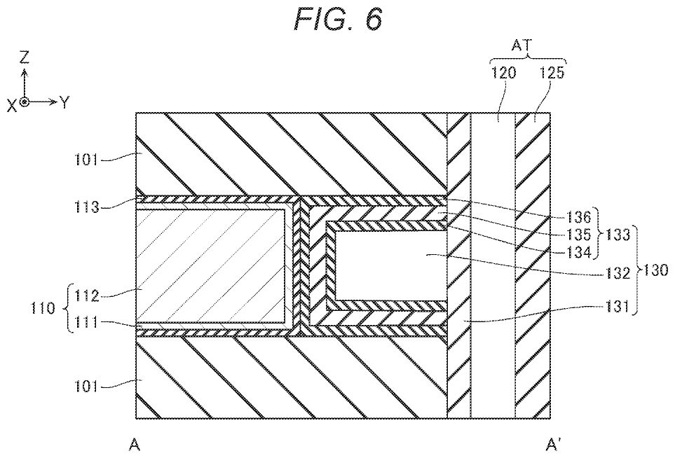

FIG. 3 is a schematic XY cross-sectional view showing a configuration of a part of the memory cell array region R_{MCA}. FIG. 4 is a schematic YZ cross-sectional view showing a configuration of a part of the memory cell array region R_{MCA}. FIG. 5 is a schematic enlarged view showing a configuration of a part of FIG. 3. FIG. 6 is a schematic cross-sectional view when the configuration shown in FIG. 5 is taken along the A-A′ line and viewed along the direction of the arrow.

The semiconductor storage device according to at least one embodiment includes, for example, a plurality of stacked body structures LS and a plurality of trench structures AT, as shown in FIGS. 3 and 4. The plurality of stacked body structures LS are arranged in the Y direction on the semiconductor substrate 100. The plurality of trench structures AT are provided between the plurality of stacked body structures LS, respectively.

The stacked body structure LS (FIG. 4) includes a plurality of insulating layers 101, a plurality of conductive layers 110, a semiconductor layer 115, and a semiconductor layer 116. The plurality of conductive layers 110, the semiconductor layer 115, and the semiconductor layer 116 are stacked in the Z direction via insulating layers 101 of silicon oxide (SiO₂) or the like, respectively.

The trench structure AT (FIG. 3) includes a plurality of semiconductor layers 120 and a plurality of gaps 150. The plurality of semiconductor layers 120 and the plurality of gaps 150 are arranged alternately in the X direction. A gate insulating layer 130 is provided between the conductive layer 110 and the semiconductor layer 120, respectively.

The semiconductor substrate 100 (FIG. 2) is, for example, a semiconductor substrate such as single crystal silicon (Si). The semiconductor substrate 100 has, for example, a double-well structure including an n-type impurity layer on the upper surface of the semiconductor substrate and a p-type impurity layer in the n-type impurity layer. The surface of the semiconductor substrate 100 may be provided with, for example, transistors, wirings, and the like that configure at least a part of the control unit CU (FIG. 1).

As shown in FIG. 6, the conductive layer 110 is, for example, a stacked film including a barrier conductive layer 111 such as titanium nitride (TiN) and a metal film 112 such as tungsten (W). The conductive layers 110 function as the word lines WL, and gate electrodes of the memory cells MC (FIG. 1), respectively. Some of the conductive layers 110 provided at the upper portion function as the drain-side select gate lines SGD and the gate electrodes of the drain-side select transistors STD (FIG. 1). As shown in FIG. 6, an insulating metal oxide layer 113 such as alumina (AlO) may cover the upper surface and the lower surface of the conductive layer 110 and a part of the side surface thereof.

In the following description, when focusing on two stacked structures LS adjacent to each other in the Y direction, the plurality of conductive layers 110 in one stacked structure LS may be referred to as conductive layers 110a (FIGS. 3 and 5). Further, the plurality of conductive layers 110 in the other stacked body structure LS may be referred to as conductive layers 110b (FIGS. 3 and 5).

The conductive layer 110a extends in the X direction. The conductive layer 110b is arranged apart from the conductive layer 110a in the Y direction and extends in the X direction. The conductive layer 110a and the conductive layer 110b are electrically independent. Therefore, different voltages can be supplied to the conductive layer 110a and the conductive layer 110b. The conductive layer 110a functions as a gate electrode of the memory cell MCa in the memory string MSa or a gate electrode of the drain-side select transistor STD in the memory string MSa. The conductive layer 110b functions as a gate electrode of the memory cell MCb in the memory string MSb or a gate electrode of the drain-side select transistor STD in the memory string MSb.

A plurality of conductive layers 110a and 110b are provided side by side in the Z direction. A plurality of memory cells MCa (FIG. 1) are provided between the plurality of conductive layers 110a and the semiconductor layer 120, respectively. A plurality of memory cells MCb (FIG. 2) are provided between the conductive layer 110b and the semiconductor layer 120, respectively.

The semiconductor layer 115 (FIG. 4) extends in the X direction. The semiconductor layer 115 is, for example, a semiconductor layer containing polycrystalline silicon (Si) or the like. The semiconductor layer 115 functions as a source-side select gate line SGS and a gate electrode of the source-side select transistor STS (FIG. 1).

The semiconductor layer 116 extends in the X direction. The semiconductor layer 116 is, for example, a semiconductor layer containing polycrystalline silicon (Si) or the like. The semiconductor layer 116 functions as a part of the source line SL.

The semiconductor layer 120 is, for example, a semiconductor layer such as undoped polycrystalline silicon (Si). The semiconductor layer 120 has a substantially bottomed square tubular shape, and an insulating layer 125 such as silicon oxide (SiO₂) is provided at a central portion thereof.

In the following description, as shown in FIG. 5, the regions in the semiconductor layer 120 may be referred to as a first region 120a, a second region 120b, a third region 120c, and a fourth region 120d, respectively.

As shown in FIG. 5, in the XY cross section, the first region 120a is provided between the conductive layer 110a and the conductive layer 110b, is arranged in the X direction, and faces the conductive layer 110a. The second region 120b is provided between the conductive layer 110a and the conductive layer 110b, is arranged in the X direction, and faces the conductive layer 110b. The third region 120c is provided between the conductive layer 110a and the conductive layer 110b and is arranged in the X direction. Further, the third region 120c is connected to one end of the first region 120a in the X direction and one end of the second region 120b in the X direction. The fourth region 120d is provided between the conductive layer 110a and the conductive layer 110b and is arranged in the X direction. Further, the fourth region 120d is connected to the other end of the first region 120a in the X direction and the other end of the second region 120b in the X direction.

Further, as shown in FIG. 4, in the YZ cross section, the first region 120a extends in the Z direction and faces the plurality of conductive layers 110a in the Y direction. The second region 120b extends in the Z direction and faces the plurality of conductive layers 110b in the Y direction.

The first region 120a functions as a channel region of the plurality of memory cells MCa in the memory string MSa (FIG. 1), and a channel region of the drain-side select transistor STD and the source-side select transistor STS. The second region 120b functions as a channel region of the plurality of memory cells MCb in the memory string MSb (FIG. 1), and a channel region of the drain-side select transistor STD and the source-side select transistor STS.

At the upper end of the semiconductor layer 120, for example, as shown in FIG. 4, a semiconductor layer 121 containing N-type impurities such as phosphorus (P) is provided. The semiconductor layer 121 is connected to a bit line BL extending in the Y direction via a bit line contact BLC such as tungsten (W).

The lower end of the semiconductor layer 120 is connected to the semiconductor layer 116, for example, as shown in FIG. 4. In such a case, the semiconductor layer 116 functions as a part of the source line SL (FIG. 1). The semiconductor layer 120 is electrically connected to the control unit CU via the semiconductor layer 116. However, such a configuration is merely an example, and the specific configuration may be adjusted as appropriate. For example, the lower end of the semiconductor layer 120 may be connected to a wiring other than the semiconductor layer 116, a semiconductor layer, or the like.

The gate insulating layer 130 (FIG. 5) includes a tunnel insulating layer 131, a charge storage layer 132, and a block insulating layer 133 provided from the semiconductor layer 120 side to the conductive layer 110 side.

The tunnel insulating layer 131 includes, for example, silicon oxide (SiO₂), silicon oxynitride (SiON), or other insulating layers. As shown in FIG. 4, for example, the tunnel insulating layer 131 may extend in the Z direction along the outer peripheral surface of the semiconductor layer 120. The tunnel insulating layer 131 may be formed on each side surface of the charge storage layer 132 in the Y direction.

The charge storage layer 132 is, for example, a floating gate such as polycrystalline silicon containing N-type impurities such as phosphorus (P) or P-type impurities such as boron (B). The charge storage layer 132 may be an insulating charge storage unit containing silicon nitride (SiN) or the like.

In the following description, when focusing on two stacked structures LS adjacent to each other in the Y direction, a plurality of charge storage layers 132 in one of the stacked structures LS may be referred to as charge storage layers 132a (FIG. 5). Further, the plurality of charge storage layers 132 in the other stacked structure LS may be referred to as charge storage layers 132b (FIG. 5).

The plurality of charge storage layers 132a are provided between the conductive layer 110a and the plurality of semiconductor layers 120, respectively. The plurality of charge storage layers 132b are provided between the conductive layer 110b and the plurality of semiconductor layers 120, respectively. For example, when the charge storage layer 132 is an insulating charge storage unit, the two charge storage layers 132a adjacent to each other in the Z direction may be separated from each other in the Z direction or may be formed in connection with each other. Further, in such a case, the two charge storage layers 132b adjacent to each other in the Z direction may be separated from each other in the Z direction or may be formed in connection with each other.

The block insulating layer 133 includes, for example, an insulating layer 134, a high dielectric constant layer 135, and an insulating layer 136, as shown in FIGS. 5 and 6.

The insulating layer 134 is, for example, silicon oxide (SiO₂) or the like, or a stacked film containing titanium nitride (TiN) and silicon oxide (SiO₂). As shown in FIG. 5, the insulating layer 134 covers a part of the outer peripheral surface of the charge storage layer 132 in the XY cross section. Further, as shown in FIG. 6, the insulating layer 134 covers the upper surface and the lower surface of the charge storage layer 132 and the side surface thereof on the conductive layer 110 side in the YZ cross section.

The high dielectric constant layer 135 includes, for example, an insulating material having a relatively high relative permittivity, such as hafnium silicate (HfSiO). As shown in FIG. 5, the high dielectric constant layer 135 covers a part of the outer peripheral surface of the charge storage layer 132 via the insulating layer 134 in the XY cross section. Further, as shown in FIG. 6, the high dielectric constant layer 135 covers the upper surface and the lower surface of the insulating layer 134 and the side surface of the insulating layer 134 on the conductive layer 110 side in the YZ cross section.

The insulating layer 136 includes, for example, an insulating layer such as silicon oxide (SiO₂). As shown in FIG. 5, the insulating layer 136 covers a part of the outer peripheral surface of the charge storage layer 132 via the high dielectric constant layer 135 in the XY cross section. As shown in FIG. 6, the insulating layer 136 covers the upper surface and the lower surface of the high dielectric constant layer 135 and the side surface thereof on the conductive layer 110 side in the YZ cross section.

As shown in FIGS. 3 and 5, the gap 150 is provided at the central portion of the trench structure AT in the Y direction. Further, the gap 150 is provided between two semiconductor layers 120 adjacent to each other in the X direction. The gap 150 refers to a space surrounded by a solid material arranged around the portion where the gap 150 is present, and the portion where the gap 150 is present does not include any solid material. The gap 150 is a space containing air or the like composed of a mixture of a plurality of gases such as nitrogen, oxygen, and a rare gas. The gap 150 may be degassed so as not to contain any gas.

Further, the gap 150 extends in the Z direction as shown in FIG. 4. The gap 150 is provided inside the insulating layer 155. The insulating layer 155 is, for example, an insulating layer such as silicon oxide (SiO₂).

An insulating layer 151 is provided above the gap 150, for example, as shown in FIG. 4. The insulating layer 151 extends from both side surface portions in the Y direction of the trench structure AT toward the central portion in the Y direction and is separated from each other to have a gap at the central portion in the Y direction. The insulating layer 151 is, for example, an insulating layer such as silicon oxide (SiO₂).

An insulating layer 156 is provided on the side surface of the trench structure AT in the Y direction. The insulating layer 156 is, for example, an insulating layer such as silicon oxide (SiO₂).

[Manufacturing Method]

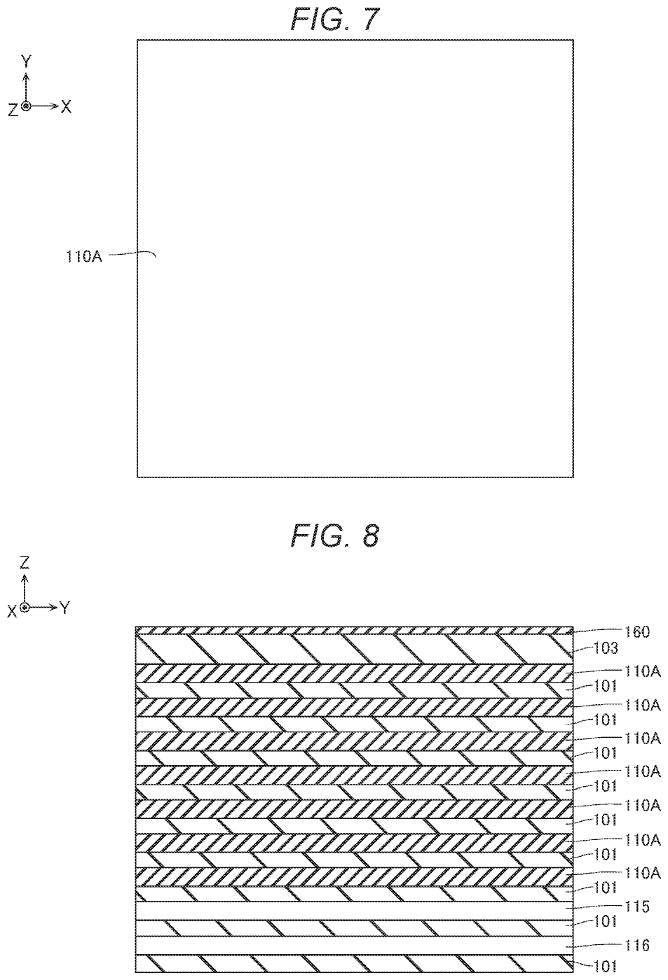

Next, a manufacturing method of the semiconductor storage device according to at least one embodiment will be described with reference to FIGS. 7 to 37. FIGS. 7, 9, 11, 13, 15, 17, 23, 26, 28, 30, 32, 34, and 36 are schematic XY cross-sectional views illustrating the manufacturing method and correspond to the portion shown in FIG. 3. FIGS. 8, 10, 12, 14, 16, 18, 19, 20, 21, 22, 24, 25, 27, 29, 31, 33, 35, and 37 are schematic YZ cross-sectional views illustrating the manufacturing method and correspond to the portion shown in FIG. 4.

As shown in FIGS. 7 and 8, in the manufacturing method, a plurality of insulating layers 101, a semiconductor layer 116, a semiconductor layer 115, and a sacrifice layer 110A are alternately stacked on the semiconductor substrate 100 (not shown), and an insulating layer 103 and an insulating layer 160 are formed thereon. The sacrifice layer 110A and the insulating layer 160 are made of, for example, silicon nitride (SiN) or the like. The insulating layer 103 is made of, for example, silicon oxide (SiO₂) or the like. The process is performed, for example, by a method such as chemical vapor deposition (CVD).

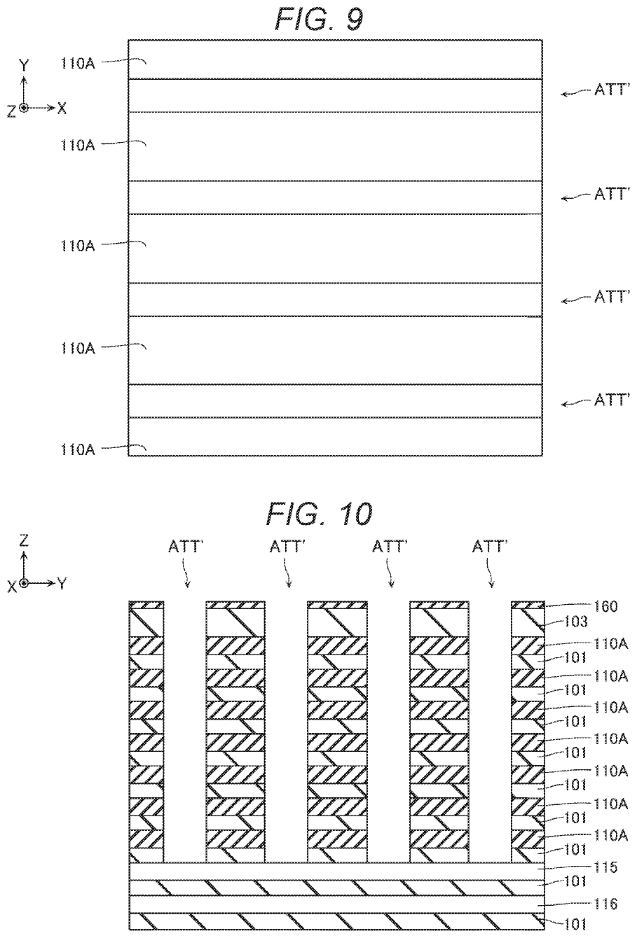

Next, as shown in FIGS. 9 and 10, a trench ATT′ is formed in the stacked structure including the insulating layer 160, the insulating layer 103, the sacrifice layer 110A, and the insulating layer 101. In the process, for example, an insulating layer having an opening in a portion corresponding to the trench ATT′ is formed on the upper surface of the structure shown in FIG. 8, and is used as a mask to perform Reactive Ion Etching (RIE) or the like. As shown in FIG. 9, the trench ATT′ extends in the X direction. Further, as shown in FIG. 10, the trench ATT′ extends in the Z direction and penetrates the insulating layer 160, the insulating layer 103, the plurality of sacrifice layers 110A, and the plurality of insulating layers 101, and these configurations are divided in the Y direction.

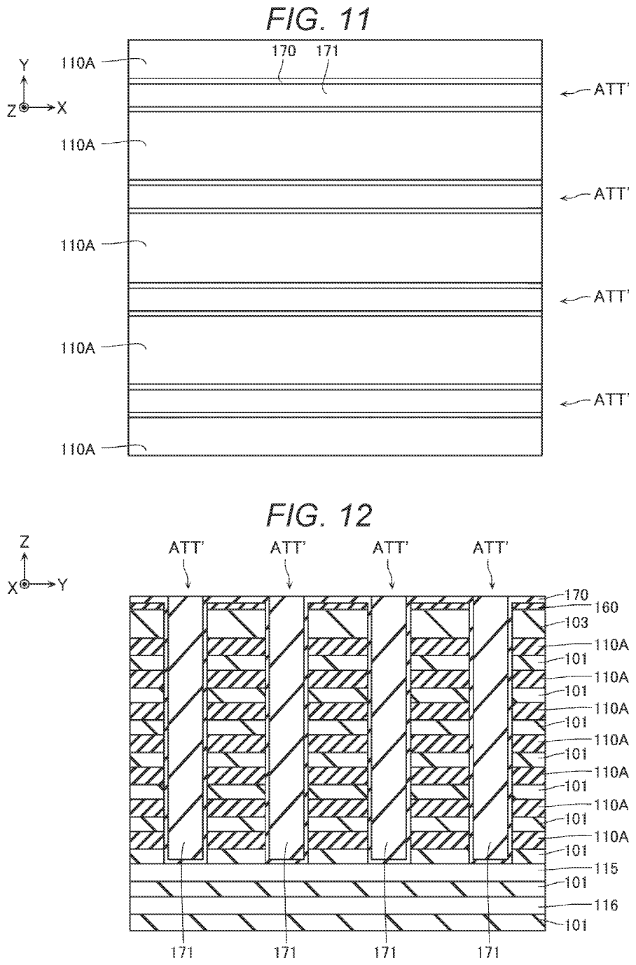

Next, as shown in FIGS. 11 and 12, an insulating layer 170 is formed on the upper surface of the insulating layer 160 and the bottom surface and the side surface of the trench ATT′. The insulating layer 170 is made of, for example, silicon oxide (SiO₂) or the like. The process is performed by, for example, a method such as CVD.

Further, a carbon film 171 burying the trench ATT′ is formed on the upper surface of the insulating layer 170. The carbon film 171 is formed by, for example, spin coating of a coating type carbon material. Further, the upper portion of the carbon film 171 is removed up to the same position as the upper surface of the insulating layer 170. The carbon film 171 is removed by, for example, RIE.

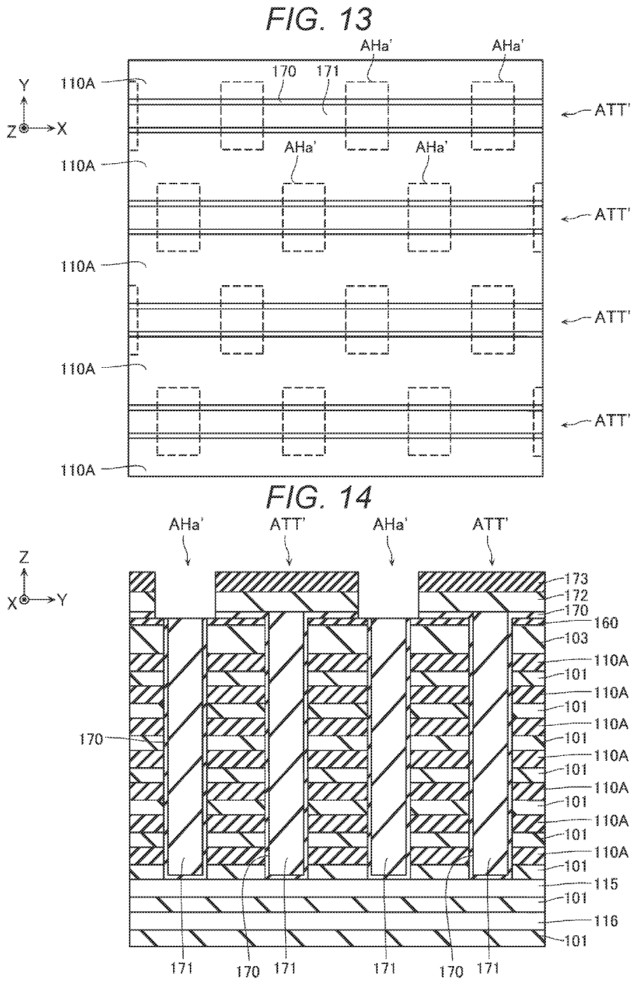

Next, as shown in FIGS. 13 and 14, a hard mask 172 and a resist 173 are formed on the upper surface of the structure shown in FIG. 12. The hard mask 172 is made of, for example, silicon oxide (SiO₂) or the like. The hard mask 172 is formed by, for example, CVD. The resist 173 is formed by spin coating of a resist material, for example.

Further, an opening AHa′ is formed by using the resist 173 having the predetermined patterning as a mask. The opening AHa′ penetrates the resist 173, the hard mask 172, and the insulating layer 170 to expose the carbon film 171. The opening Aha′ is formed by, for example, a method such as photolithography and RIE.

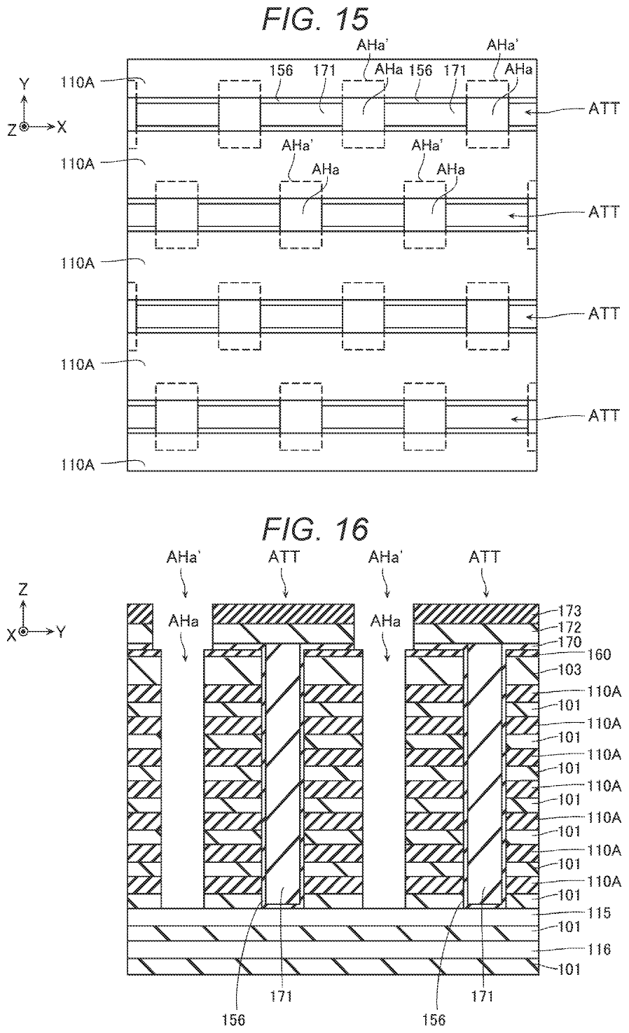

Next, as shown in FIGS. 15 and 16, the portion of the carbon film 171 and the insulating layer 170 provided at the position corresponding to the opening AHa′ is removed to form an opening AHa. Further, by the process, an insulating layer 156 is formed on the inner wall and the bottom surface of the trench ATT. The process of removing the carbon film 171 is performed by, for example, RIE or the like. The process of removing the insulating layer 170 is performed by, for example, chemical dry etching or the like. Hereinafter, a plurality of portions of the trench ATT′ divided by a plurality of openings AHa arranged in the X direction are referred to as trenches ATT, respectively.

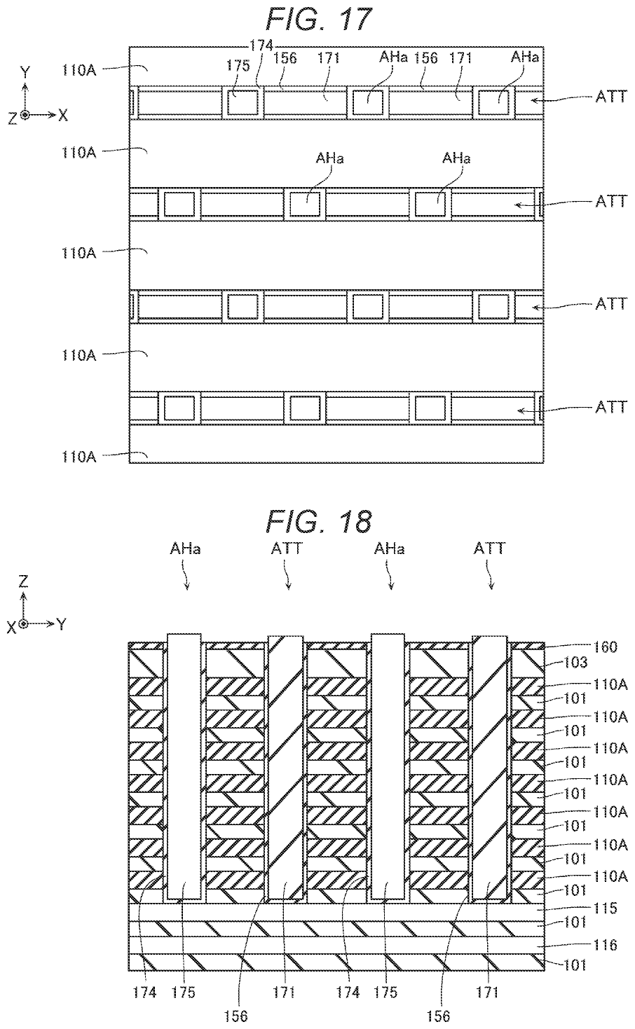

Next, as shown in FIGS. 17 and 18, an insulating layer 174 such as silicon oxide (SiO₂) is formed on the bottom surface and the side surface of the opening AHa. Further, a semiconductor layer 175 such as amorphous silicon (Si) in which the opening AHa is buried is formed on the upper surface of the insulating layer 174. Further, the resist 173, the hard mask 172, and the insulating layer 170 are removed to expose the upper surface of the insulating layer 160. The insulating layer 174 and the semiconductor layer 175 are formed by, for example, a method such as CVD. The process of removing the resist 173, the hard mask 172, and the insulating layer 170 is performed by, for example, RIE or the like.

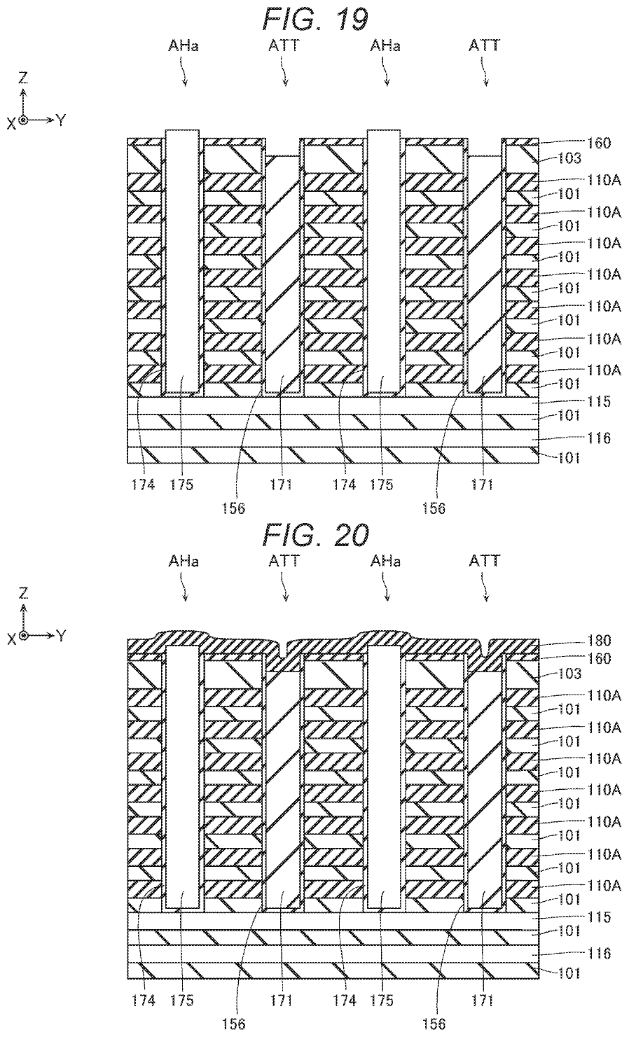

Next, as shown in FIG. 19, a part of the carbon film 171 is removed from the inside of the trench ATT. By the process, the upper surface of the carbon film 171 is positioned below the upper surface of the insulating layer 103. The process is performed, for example, by RIE or the like.

Next, as shown in FIG. 20, an insulating layer 180 such as silicon oxide (SiO₂) is formed on the upper surface of the structure shown in FIG. 19. The process is performed by, for example, a method such as CVD or the like.

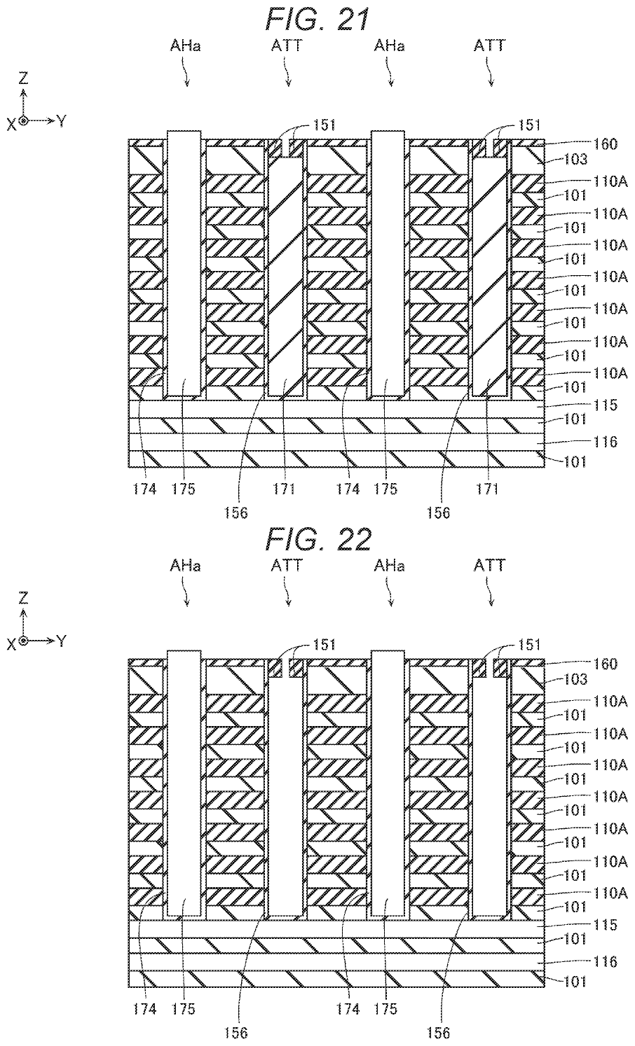

Next, as shown in FIG. 21, a part of the insulating layer 180 is removed up to a position where the insulating layer 160 is exposed to form the insulating layer 151. The process is performed by, for example, a method such as RIE, which has a high etching rate in the Z direction.

Next, as shown in FIG. 22, the carbon film 171 is removed from the inside of the trench ATT through the gap in the Y direction of the insulating layer 151. This process is performed, for example, by ashing or the like.

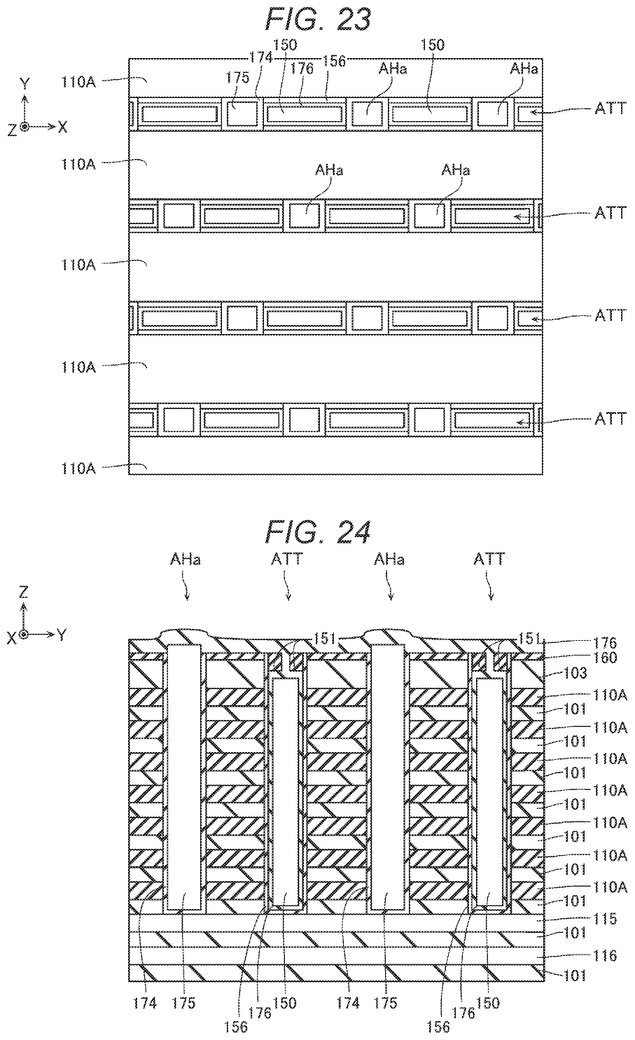

Next, as shown in FIGS. 23 and 24, an insulating layer 176 is formed inside the trench ATT through a gap in the Y direction of the insulating layer 151.

The insulating layer 176 is formed on the side surface and the bottom surface of the trench ATT. Further, the insulating layer 176 covers the lower surface, the gap in the Y direction, and the upper surface of the insulating layer 151, and the upper surface of the insulating layer 160. The process is performed by, for example, a method such as CVD or the like.

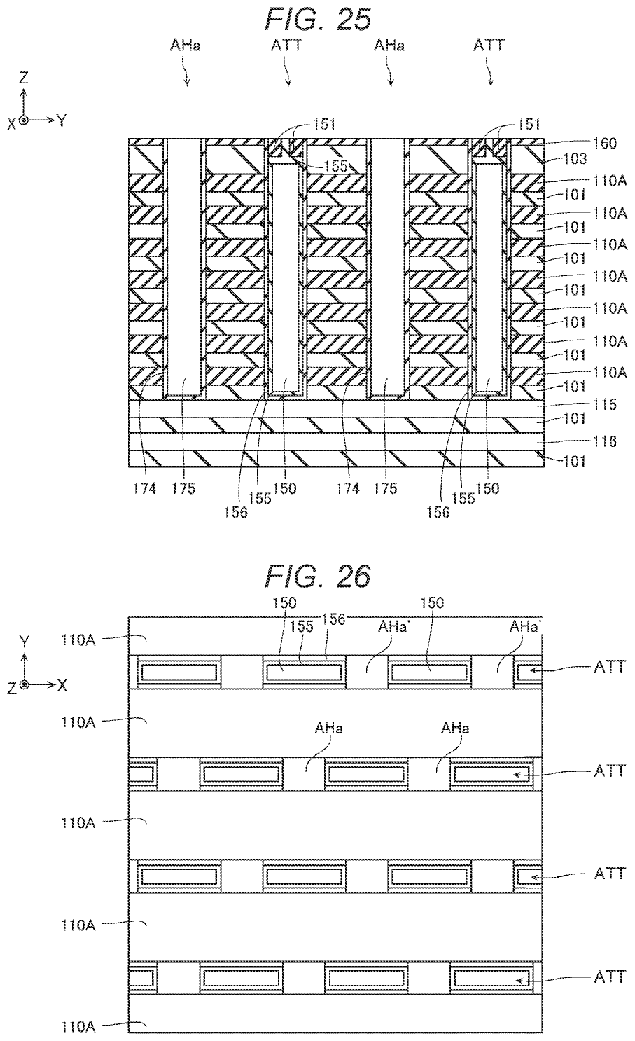

Next, as shown in FIG. 25, a part of the insulating layer 176 is removed up to a position where the insulating layer 160 is exposed. By the process, the insulating layer 155 surrounding the gap 150 is formed. The process is performed by, for example, a method such as RIE or the like.

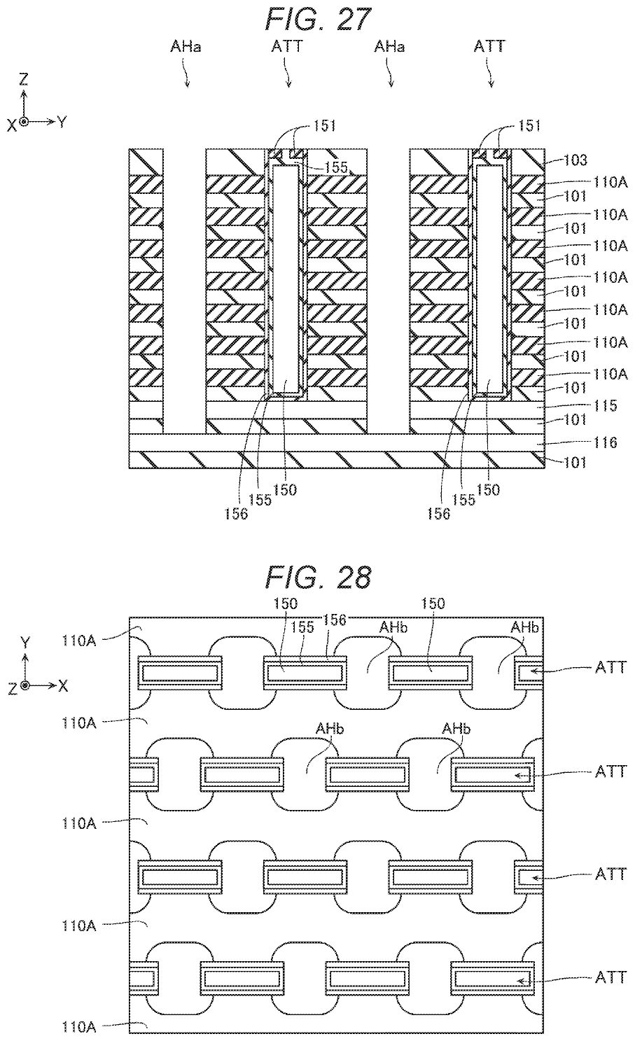

Next, as shown in FIGS. 26 and 27, the semiconductor layer 175 inside the opening AHa is removed. Further, the insulating layer 174, the semiconductor layer 115, and the insulating layer 101 located on the bottom surface of the opening AHa are removed to expose the semiconductor layer 116. Further, the insulating layer 174 on the side wall of the opening AHa and the insulating layer 160 on the upper surface of the insulating layer 103 are removed. The process of removing the semiconductor layer 175 is performed by, for example, wet etching. The process of removing the insulating layer 174, the semiconductor layer 115, the insulating layer 101, and the insulating layer 160 is performed by, for example, RIE or the like.

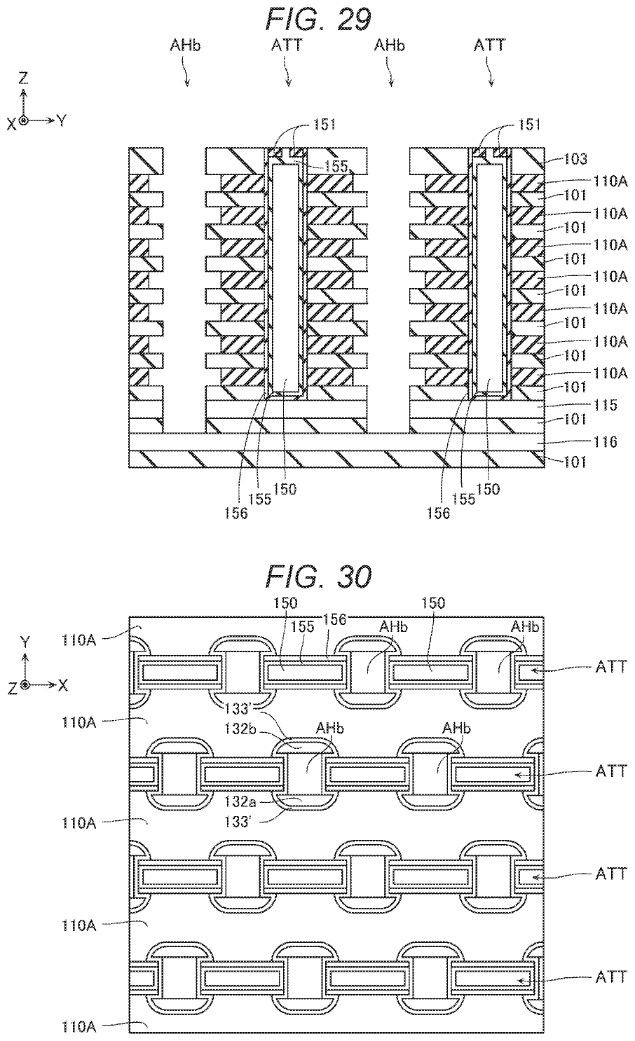

Next, as shown in FIGS. 28 and 29, a part of the sacrifice layer 110A is removed through the opening AHa to form an opening AHb. By the process, the portions of the upper surface and the lower surface of the insulating layer 101 located in the vicinity of the opening AHa are exposed. The process is performed, for example, by wet etching or the like.

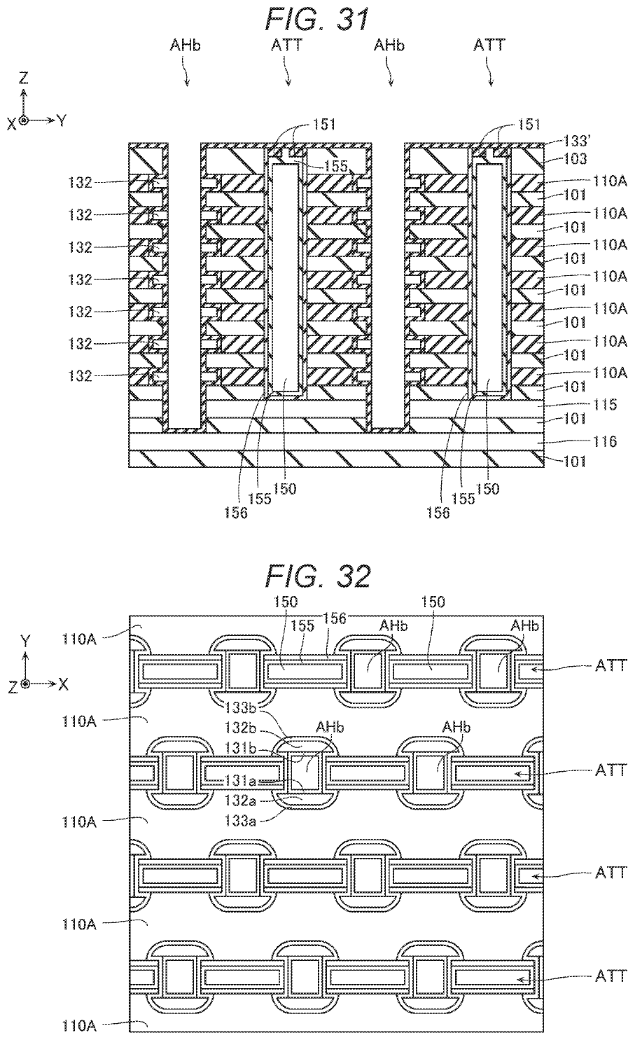

Next, as shown in FIGS. 30 and 31, an insulating layer 133′ and the charge storage layer 132 are sequentially formed on the side surface of the opening AHb through the opening AHb. The insulating layer 133′ is formed by forming the insulating layer 136, the high dielectric constant layer 135, and the insulating layer 134, which are not shown, in this order. Further, a semiconductor layer made of the same material as the charge storage layer 132, for example, polycrystalline silicon (Si), is formed on the side surface of the opening AHb via the opening AHb, and then a part of the semiconductor layer is removed to form a plurality of charge storage layers 132 arranged in the Z direction corresponding to the sacrifice layer 110A. The process is performed by, for example, CVD, wet etching, or the like.

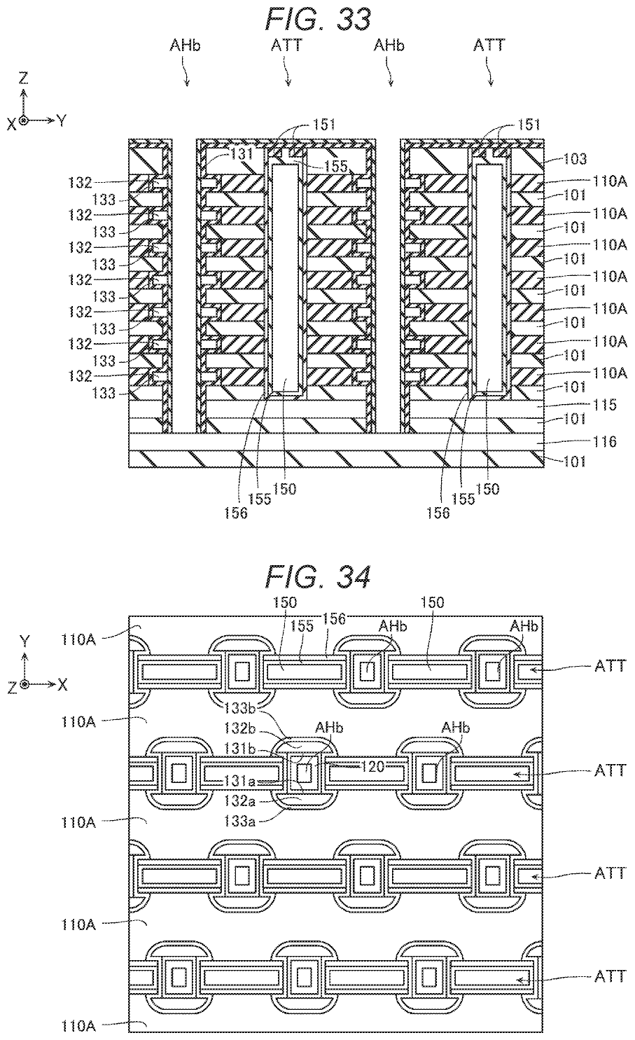

Next, as shown in FIGS. 32 and 33, the tunnel insulating layer 131 is formed on the inner peripheral surface of the opening AHb. The process is performed by, for example, CVD or the like. Further, the portion of the tunnel insulating layer 131 that covers the bottom surface of the opening AHb is removed. The process is performed, for example, by RIE or the like.

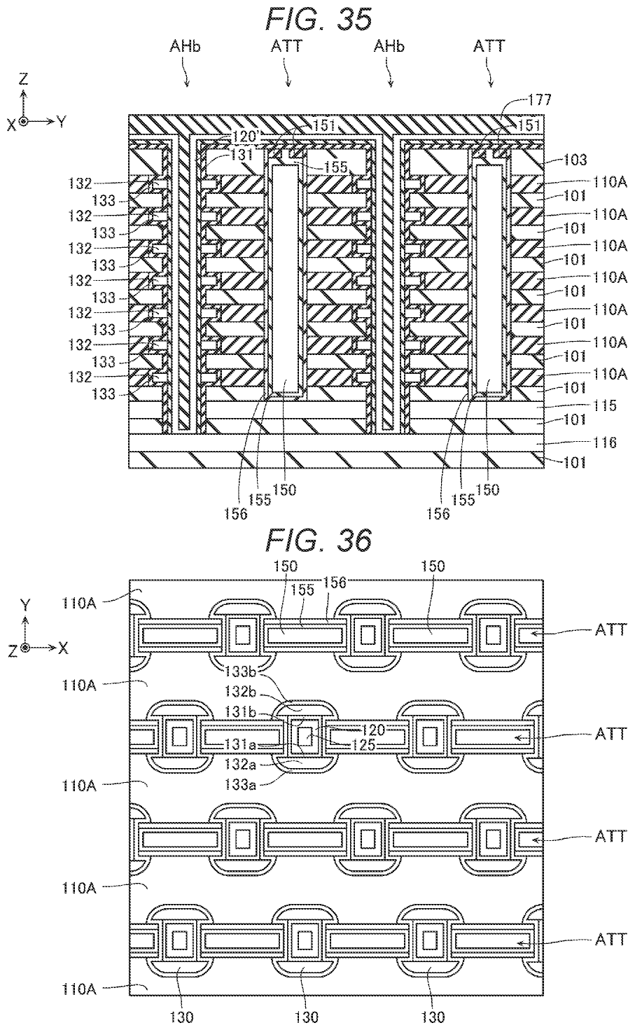

Next, as shown in FIGS. 34 and 35, a semiconductor layer 120′ and an insulating layer 177 are formed inside the opening AHb. The process is performed by, for example, CVD or the like.

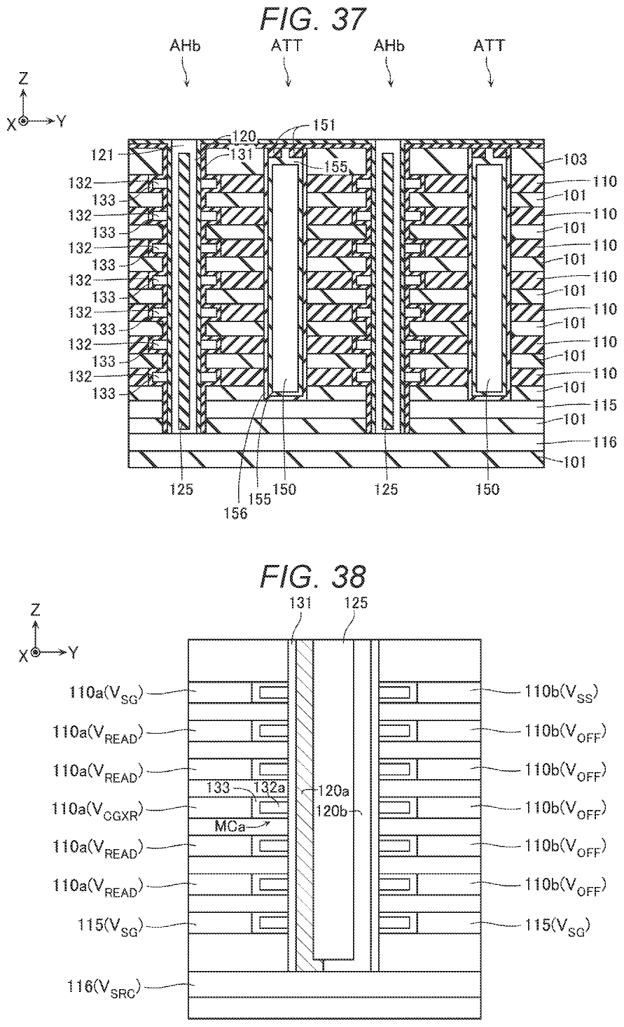

Next, as shown in FIGS. 36 and 37, a part of the insulating layer 177 is removed up to a position below the upper surface of the insulating layer 103 inside the opening AHb to form the insulating layer 125. Further, a part of the semiconductor layer 120′ is removed inside the opening AHb, and the semiconductor layer 121 connected to the upper surface of the semiconductor layer 120 is formed on the upper portion thereof. The process is performed by, for example, RIE, CVD, or the like.

Next, the plurality of sacrifice layers 110A are removed through openings (not shown). The process is performed, for example, by wet etching or the like.

Next, as shown in FIG. 6, the metal oxide layer 113 and the barrier conductive layer 111 are formed on the upper surface and the lower surface of the insulating layer 101 and the side surface of the insulating layer 136 in the Y direction through an opening (not shown). Further, as shown in FIGS. 4 and 6, the conductive layer 110 is formed so as to bury the cavity formed by removing the plurality of sacrifice layers 110A. The process is performed by, for example, CVD or the like.

After that, the semiconductor storage device according to the first embodiment is manufactured by forming the bit line contact BLC, the bit line BL, and the like.

[Read Operation]

Next, the read operation of the semiconductor storage device according to the present embodiment will be described with reference to FIG. 38. FIG. 38 is a schematic cross-sectional view illustrating the read operation. FIG. 38 illustrates an example in which a read operation is executed for a predetermined memory cell MCa in the memory string MSa.

As shown in FIG. 38, in the read operation, the read voltage V_{CGXR} is supplied to the conductive layer 110a functioning as the selected word line WL, and a read pass voltage V_{READ} is supplied to the conductive layer 110a functioning as the non-selected word line WL. The voltage V_{SG} is supplied to the conductive layer 110a functioning as the drain-side select gate line SGD. Further, in the read operation, the read cutoff voltage V_{OFF} is supplied to the plurality of conductive layers 110b functioning as the word line WL, and the ground voltage V_{SS} is supplied to the conductive layer 110b functioning as the drain-side select gate line SGD. Further, in the read operation, the voltage V_{SG} is supplied to the semiconductor layer 115 functioning as the source-side select gate line SGS, and the source voltage V_{SRC} is supplied to the semiconductor layer 116 functioning as the source line SL.

The read voltage V_{CGXR} is a voltage to an extent that turns the memory cell MCa into an ON state or an OFF state according to the data recorded in the memory cell MCa. For example, when the threshold voltage of the memory cell MCa is controlled in n states (n is an integer of 2 or more), the read voltage V_{CGXR} is controlled in at least n−1 states. The read pass voltage V_{READ} is a voltage to an extent at which the memory cell MCa is turned on regardless of the data recorded in the memory cell MCa, and is larger than the maximum value of the read voltage V_{CGXR}. The read cutoff voltage V_{OFF} is a voltage to an extent at which the memory cell MCa is turned off regardless of the data recorded in the memory cell MCa, and is smaller than the minimum value of the read voltage V_{CGXR}. The read cutoff voltage V_{OFF} may be smaller than, for example, the ground voltage V_{SS}. That is, the read cutoff voltage V_{OFF} may have a negative polarity. The voltage V_{SG} is a voltage to an extent at which the drain-side select transistor STD and the source-side select transistor STS are turned on, and is larger than the ground voltage V_{SS}. The source voltage V_{SRC} is a voltage as large as the ground voltage V_{SS} and is larger than the ground voltage V_{SS}.

As a result, an electron channel is formed in the first region 120a of the semiconductor layer 120. The electron channel conducts the channel region from the bit line BL to the selected memory cell MCa. Further, the electron channel conducts the channel region from the selected memory cell MCa to the source line SL. The selected memory cell MCa is turned on or off depending on the amount of charge stored in the charge storage layer 132a of the selected memory cell MCa. The ON state or the OFF state is determined by the peripheral circuit PC (FIG. 1). The determination is performed, for example, by detecting the high or low voltage of the bit line BL or the magnitude of the current flowing through the bit line BL. In this way, the data recorded in the memory cell MCa is determined.

In FIG. 38, the read cutoff voltage V_{OFF} is supplied to all the conductive layers 110b that function as the word line WL. However, such a method is merely an example, and a specific method may be adjusted as appropriate. For example, the read cutoff voltage V_{OFF} is supplied only to the conductive layer 110b adjacent in the Y direction to the conductive layer 110a that functions as the selected word line WL, and the ground voltage V_{SS} and the read pass voltage V_{READ} or other voltage may be supplied to the other conductive layers 110b that function as the word line WL.

[Write Operation]

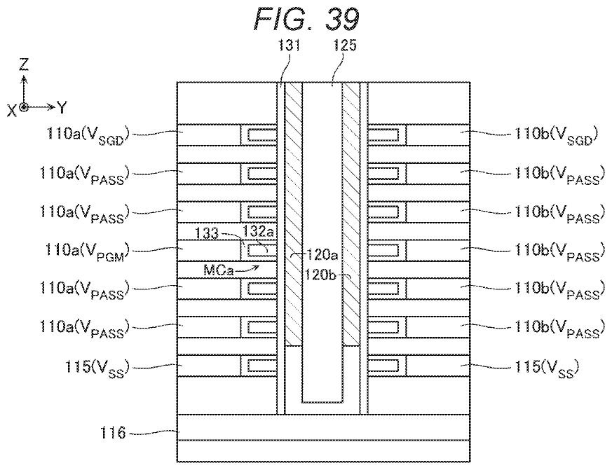

Next, the write operation of the semiconductor storage device according to the present embodiment will be described with reference to FIG. 39. FIG. 39 is a schematic cross-sectional view illustrating the write operation. FIG. 39 illustrates an example in which a write operation is executed for a predetermined memory cell MCa in the memory string MSa.

In the write operation, a program voltage V_{PGM} is supplied to the conductive layer 110a that functions as the selected word line WL, and a write pass voltage V_{PASS} is supplied to the conductive layer 110a and the conductive layer 110b that function as the non-selected word line WL. Further, in the write operation, the voltage V_{SGD} is supplied to the conductive layer 110a and the conductive layer 110b that function as the drain-side select gate line SGD, and the ground voltage V_{SS} is supplied to the conductive layer 110a and the conductive layer 110b that function as the source-side select gate line SGS.

The program voltage V_{PGM} is a voltage sufficient to store electrons in the charge storage layer 132a of the selected memory cell MCa and is larger than the above-mentioned read pass voltage V_{READ}. The write pass voltage V_{PASS} is a voltage to an extent at which the memory cell MCa and the memory cell MCb are turned on regardless of the data recorded in the memory cell MCa and is the same as or larger than the above-mentioned read pass voltage V_{READ} and smaller than the program voltage V_{PGM}. The voltage V_{SGD} is a voltage to an extent at which the drain-side select transistor STD is turned on when the source voltage V_{SRC} is supplied to the bit line BL, and the drain-side select transistor STD is turned off when a predetermined drive voltage is supplied to the bit line BL. The voltage V_{SGD} is larger than the ground voltage V_{SS} and smaller than the voltage V_{SG} described above.

As a result, an electron channel that conducts the bit line BL and the channel region of the selected memory cell MCa is formed in the first region 120a of the semiconductor layer 120. Further, electrons in the channel region of the selected memory cell MCa tunnel through the tunnel insulating layer 131 and are stored in the charge storage layer 132a.

When the above-mentioned write operation executes a plurality of times for the semiconductor storage device according to the present embodiment, charges are gradually stored in the charge storage layer 132, and the threshold voltage of the memory cell MC gradually increases. In the present embodiment, the threshold voltage of the memory cell MC is controlled to two or more states by such a method, and thereby data is stored.

[Effect of First Embodiment]

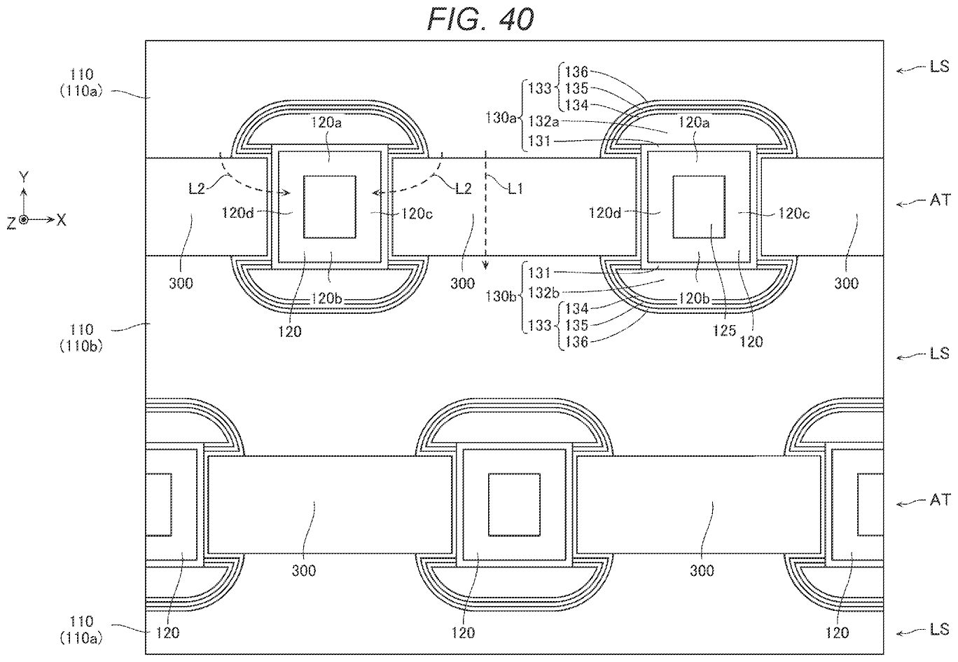

FIG. 40 shows the configuration of the semiconductor storage device according to the comparative example. FIG. 40 is a schematic cross-sectional view showing the configuration of the portion corresponding to FIG. 5.

Unlike the first embodiment, the semiconductor storage device according to the comparative example does not include the gap 150 between the semiconductor layers 120 adjacent to each other in the X direction. The semiconductor storage device according to the comparative example includes an insulating layer 300 such as silicon oxide (SiO₂) between the semiconductor layers 120 adjacent to each other in the X direction.

Here, for example, in the comparative example in which the gap 150 as in the present embodiment is not arranged and the insulating layer 300 is provided, the threshold voltage of the memory cell MC does not increase favorably with respect to the write operation as described above in some cases. It is considered to be due to the following phenomenon.

That is, after the write operation described with reference to FIG. 39 is executed, the read operation described with reference to FIG. 38 is executed, and when a current flows through the bit line BL, it is determined that the threshold voltage of the memory cell MC does not reach the target value. Further, when no current flows through the bit line BL, it is determined that the threshold voltage of the memory cell MC reaches the target value. Here, when the read operation is executed in the semiconductor storage device according to the comparative example, electron channels are formed in the portions near both ends of the third region 120c and the fourth region 120d of the semiconductor layer 120 in the Y direction, which becomes leak pass and current flows in some cases. In such a case, even if electrons having a sufficient amount of charge are stored in the charge storage layer 142 of the selected memory cell MC in the write operation, the threshold voltage of the memory cell MC may not reach the target value.

Further, with the high integration of semiconductor storage devices, the width of the trench structure AT in the Y direction is being reduced. With such a reduction in the width in the Y direction, due to the path shown by the virtual line L1 (FIG. 40), a leak easily occurs between the conductive layers 110a and 110b facing each other in some cases.

Therefore, in the present embodiment, as shown in FIGS. 3 to 5, for example, the gap 150, which is a region having a low relative permittivity, is arranged between the semiconductor layers 120 adjacent to each other in the X direction. As a result, for example, when the read operation is executed after the write operation is performed, the gap 150 is present in the middle of the path indicated by the virtual line L2, and thus, it is possible to prevent the application of a strong electric field to the third region 120c and the fourth region 120d. As a result, it is possible to provide a semiconductor storage device that prevents the formation of leak pass in the third region 120c and the fourth region 120d in the write operation, appropriately controls the threshold voltage of the memory cell MC, and operates suitably.

Further, in at least one embodiment, since the gap 150 is present in the middle of the path indicated by the virtual line L1, it is possible to prevent the leak generated between the conductive layer 110a and the conductive layer 110b facing each other. As a result, it is possible to provide a semiconductor storage device that can be suitably highly integrated.

### Second Embodiment

[Configuration]

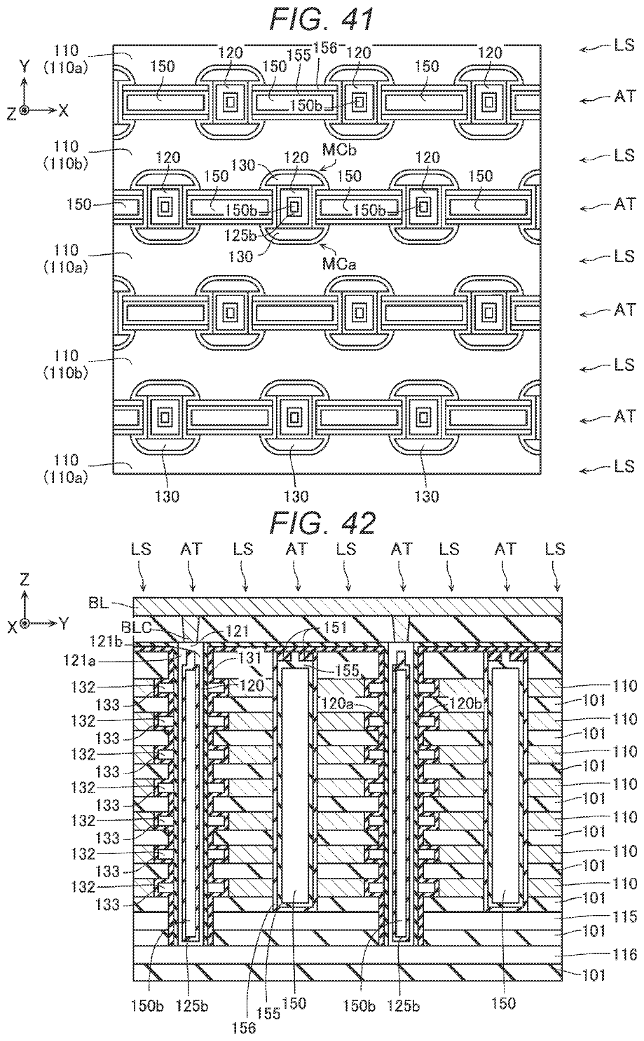

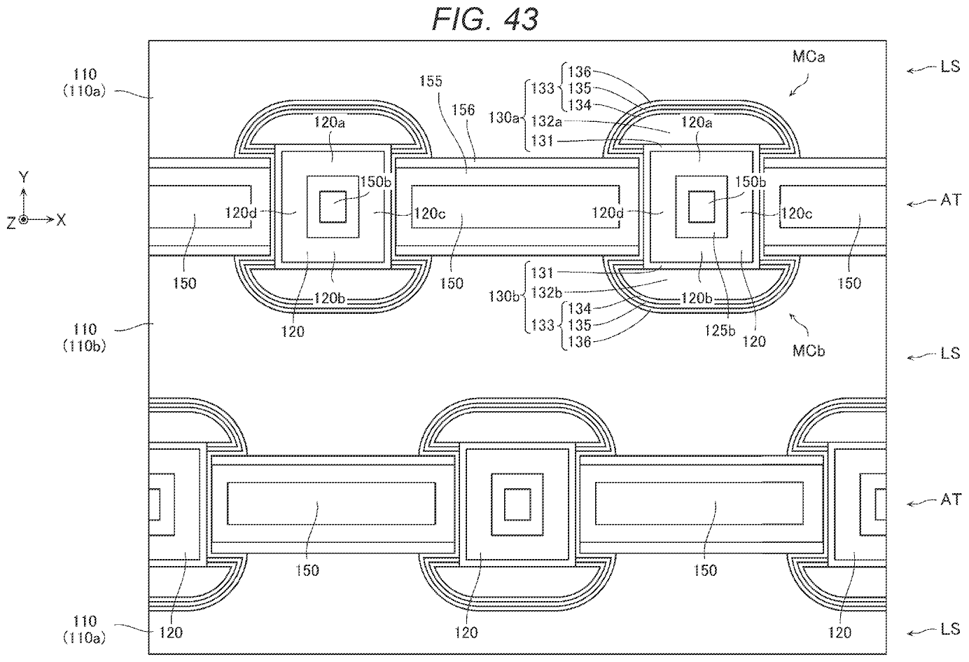

Next, the semiconductor storage device according to the second embodiment will be described with reference to FIGS. 41 to 43. FIG. 41 is a schematic XY cross-sectional view showing a partial configuration of the memory cell array region R_{MCA}. FIG. 42 is a schematic YZ cross-sectional view showing a partial configuration of the memory cell array region R_{MCA}. FIG. 43 is a schematic enlarged view showing a partial configuration of FIG. 41.

The semiconductor storage device according to the second embodiment is basically configured in the same manner as the semiconductor storage device according to the first embodiment. However, unlike the first embodiment, the semiconductor storage device according to the second embodiment includes a gap 150b between the first region 120a and the second region 120b. Further, the semiconductor storage device according to the second embodiment includes an insulating layer 125b instead of the insulating layer 125.

As shown in FIGS. 41 to 43, the gap 150b is provided at the central portion of the trench structure AT in the Y direction. Further, as shown in FIG. 43, the gaps 150b are provided between the pair of first regions 120a and the second regions 120b that are adjacent to each other in the Y direction. The gap 150b refers to a so-called space surrounded by a solid material arranged around the portion where the gap 150b is present, and the portion where the gap 150b is present does not include any solid material. The gap 150b is a space containing air or the like composed of a mixture of a plurality of gases such as nitrogen, oxygen, and a rare gas. The gap 150b may be degassed so as not to contain any gas.

Further, the gap 150b extends in the Z direction as shown in FIG. 42. The gap 150b is provided inside the insulating layer 125b. The insulating layer 125b is, for example, an insulating layer such as silicon oxide (SiO₂).

Above the gap 150b, for example, as shown in FIG. 42, a semiconductor layer 121a and a semiconductor layer 121b are provided. The semiconductor layer 121a and the semiconductor layer 121b extend from both side surface portions in the Y direction of the trench structure AT toward the central portion in the Y direction and are separated from each other to have a gap at the central portion in the Y direction.

[Manufacturing Method]

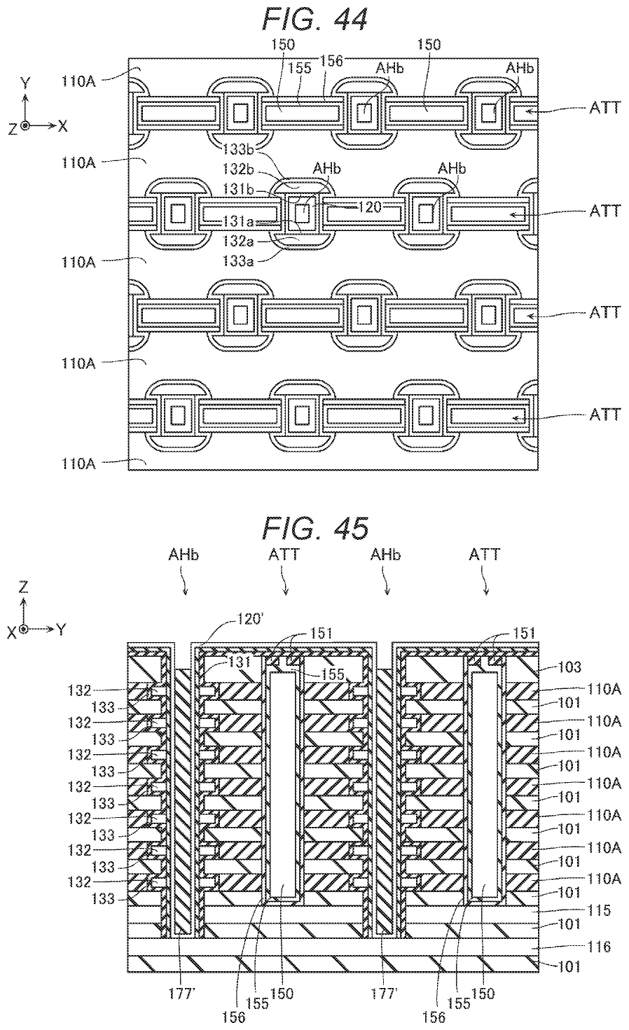

Next, a manufacturing method of the semiconductor storage device according to the second embodiment will be described with reference to FIGS. 44 to 52. FIGS. 44 and 49 are schematic XY cross-sectional views illustrating the manufacturing method and correspond to the portion shown in FIG. 41. FIGS. 45, 46, 47, 48, 50, 51, and 52 are schematic YZ cross-sectional views illustrating the manufacturing method and correspond to the portion shown in FIG. 42.

In manufacturing the semiconductor storage device according to the second embodiment, the processes described with reference to FIGS. 7 to 35 are executed.

Next, as shown in FIGS. 44 and 45, a part of the insulating layer 177 is removed from the upper surface of the structure shown in FIG. 35 to form the insulating layer 177′ inside the opening AHb. The upper surface position of the insulating layer 177′ is formed so as to be lower than the upper surface position of the insulating layer 103. The process is performed, for example, by RIE or the like.

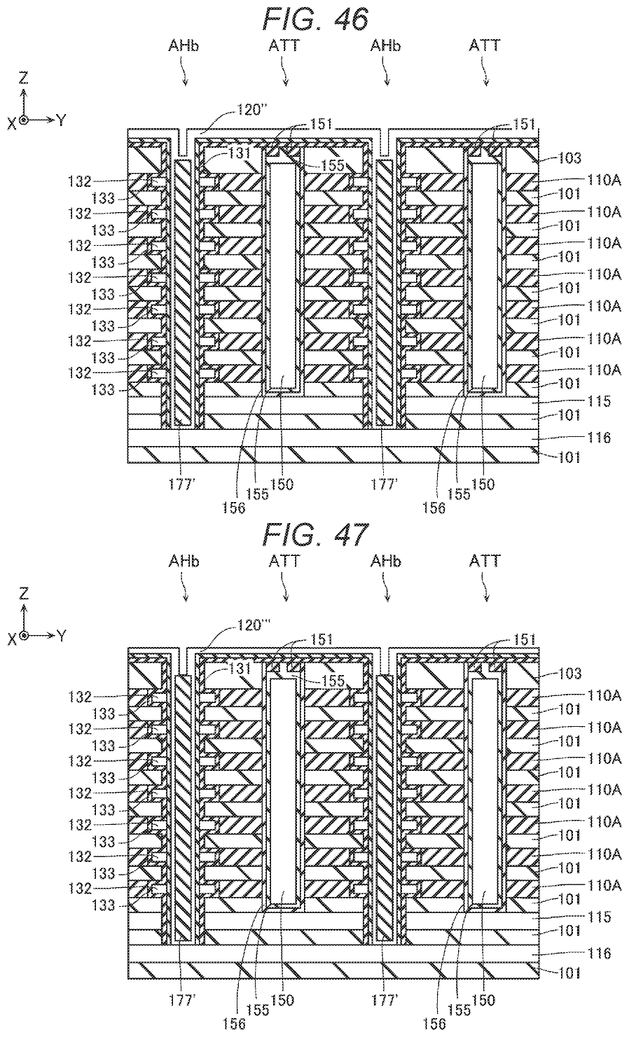

Next, as shown in FIG. 46, a semiconductor layer containing polycrystalline silicon (Si) or the like is formed on the upper surface of the semiconductor layer 120′ shown in FIG. 45, and a semiconductor layer 120″ such as polycrystalline silicon (Si) having a larger thickness than the semiconductor layer 120′ is formed. As a result, the opening width of the semiconductor layer 120″ in the opening AHb in the Y direction becomes narrower than that before the formation of the semiconductor layer 120″. The process is performed by, for example, CVD or the like.

Next, as shown in FIG. 47, the upper surface of the semiconductor layer 120″ is etched back from the upper surface of the structure shown in FIG. 46 to form the semiconductor layer 120′″ such as polycrystalline silicon (Si). As a result, the upper surface of the insulating layer 177′ is exposed in the opening AHb. In the process, the opening width of the semiconductor layer 120′″ in the opening AHb in the Y direction does not change as compared with that before the formation of the semiconductor layer 120′″. The process is performed, for example, by RIE or the like.

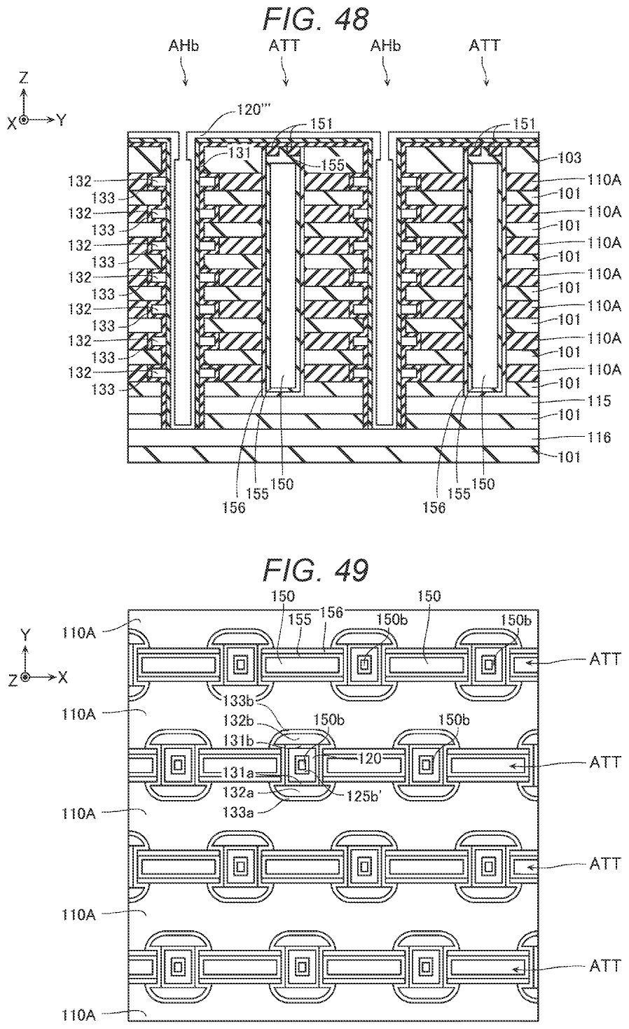

Next, as shown in FIG. 48, the insulating layer 177′ inside the opening AHb is removed through the gap in the Y direction of the semiconductor layer 120′″ in the opening AHb. The process is performed, for example, by wet etching or the like.

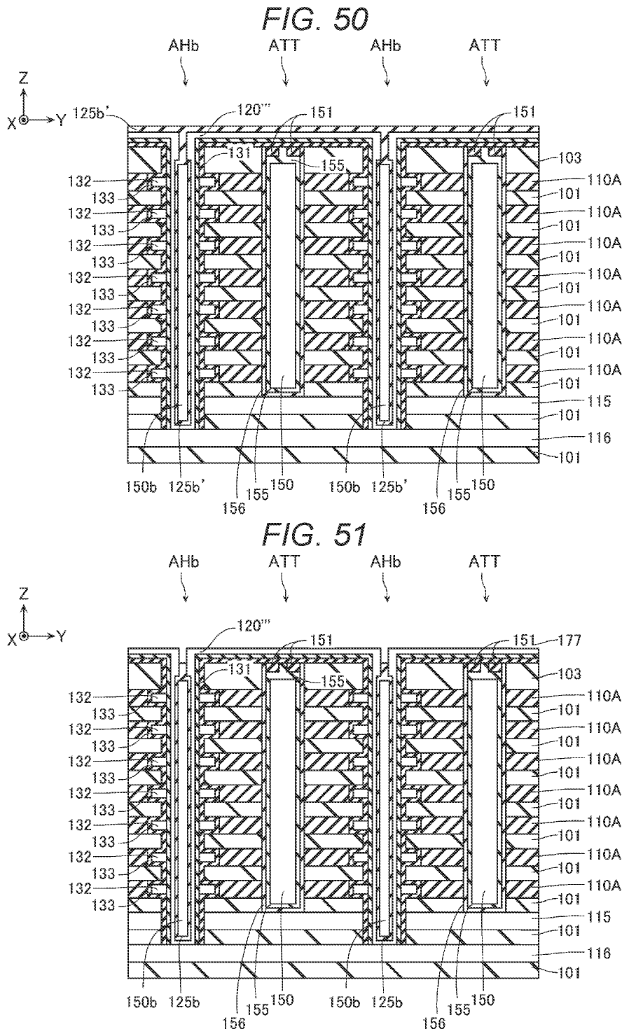

Next, as shown in FIGS. 49 and 50, an insulating layer 125b′ is formed inside the opening AHb through a gap in the Y direction of the semiconductor layer 120′″. The insulating layer 125b′ is formed on the side surface and the bottom surface of the opening AHb. Further, the insulating layer 125b′ covers the bottom surface, the gap in the Y direction, and the top surface of the semiconductor layer 120′″. The process is performed by, for example, a method such as CVD or the like.

Next, as shown in FIG. 51, a part of the insulating layer 125b′ inside the opening AHb is removed through the opening AHb to form the upper surface of the insulating layer 125b′ which is lower than the upper surface of the insulating layer 103. The process is performed, for example, by RIE or the like.

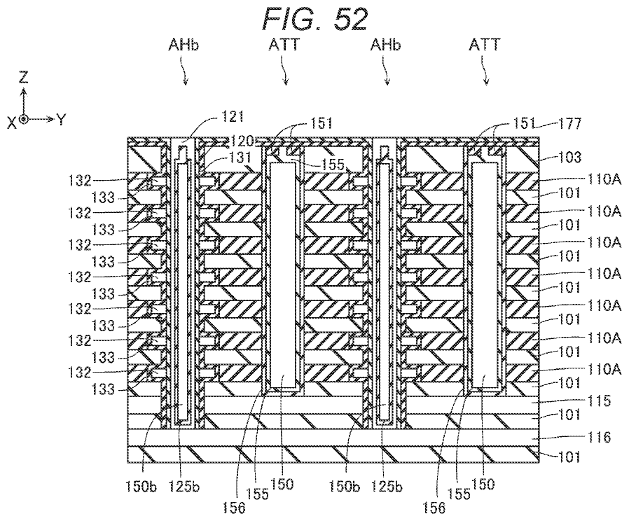

Next, as shown in FIG. 52, a semiconductor layer containing polycrystalline silicon (Si) or the like is formed on the upper surface of the semiconductor layer 120′″ shown in FIG. 51 and then is etched back to form the semiconductor layer 121 connected to the upper surface of the semiconductor layer 120. The process is performed by, for example, CVD, RIE, or the like.

Next, the plurality of sacrifice layers 110A are removed through openings (not shown). The process is performed, for example, by wet etching or the like.

Next, as shown in FIG. 6, the metal oxide layer 113 and the barrier conductive layer 111 are formed on the upper surface and the lower surface of the insulating layer 101 and the side surface of the insulating layer 136 in the Y direction through an opening (not shown). Further, as shown in FIG. 40, the conductive layer 110 is formed so as to bury the cavity formed by removing the plurality of sacrifice layers 110A. The process is performed by, for example, CVD or the like.

After that, the semiconductor storage device according to the second embodiment is manufactured by forming the bit line contact BLC, the bit line BL, and the like.

[Effects of Second Embodiment]

The effects of the second embodiment will be described with reference to the comparative example shown in FIG. 40. In the comparative example, as shown in FIG. 40, the insulating layer 125 is provided inside the semiconductor layer 120. In such a structure, the memory cell MCa and the memory cell MCb facing each other may be capacitively coupled via the insulating layer 125 and interfere with each other, which may hinder high-precision read and write operations for the memory cells.

Therefore, in at least one embodiment, as shown in FIGS. 41 and 43, a gap 150b, which is a region having a low relative permittivity, is provided between the memory cell MCa and the memory cell MCb facing each other. As a result, it is possible to provide a semiconductor storage device that reduces capacitive coupling between the memory cell MCa and the memory cell MCb facing each other, reduces interference between the two cells, and operates suitably.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a first conductive layer extending in a first direction;
a second conductive layer extending in the first direction and spaced from the first conductive layer in a second direction intersecting the first direction;
a plurality of semiconductor layers arranged in the first direction and disposed between the first conductive layer and the second conductive layer, the plurality of semiconductor layers including: (i) a first region facing the first conductive layer, (ii) a second region facing the second conductive layer, (iii) a third region connected to one end of the first region in the first direction and one end of the second region in the first direction, and (iv) a fourth region connected to an other end of the first region in the first direction and an other end of the second region in the first direction;
a plurality of first memory cells disposed between the first conductive layer and the plurality of semiconductor layers, respectively;
a plurality of second memory cells disposed between the second conductive layer and the plurality of semiconductor layers, respectively, wherein
a gap exists between two semiconductor layers adjacent to each other in the first direction.

2. The semiconductor storage device according to claim 1, wherein
a plurality of first conductive layers and a plurality of second conductive layers are disposed side by side in a third direction intersecting the first direction and the second direction.

3. The semiconductor storage device according to claim 2, wherein
the first region extends in the third direction and faces the plurality of first conductive layers in the second direction, and the second region extends in the third direction and faces the plurality of second conductive layers in the second direction.

4. The semiconductor storage device according to claim 1, wherein
a gap exists between the first region and the second region.

5. The semiconductor storage device according to claim 1, wherein
a gap exists between the third region and the fourth region.

6. The semiconductor storage device according to claim 1, wherein
the plurality of semiconductor layers include a first semiconductor layer adjacent to a second semiconductor layer,
a gap exists between the third region in the first semiconductor layer and the fourth region in the second semiconductor layer.

7. The semiconductor storage device according claim 1, further comprising:
a plurality of first charge storage layers disposed between the first conductive layer and the plurality of semiconductor layers, respectively; and
a plurality of second charge storage layers disposed between the second conductive layer and the plurality of semiconductor layers, respectively, wherein
two first charge storage layers are adjacent to and spaced from each other in the first direction, and two second charge storage layers are adjacent to and spaced from each other in the first direction.

8. The semiconductor storage device according to claim 1, wherein the second region functions as a channel of the second memory cells.

9. The semiconductor storage device according to claim 1, wherein the first region functions as a channel of the first memory cells.

10. The semiconductor storage device according to claim 1, wherein the semiconductor storage device includes a memory cell array.

11. The semiconductor storage device according to claim 1, wherein the gap does not include solid materials.

12. The semiconductor storage device according to claim 7, wherein the first charge storage layers act as a floating gate.

13. The semiconductor storage device according to claim 12, wherein the first charge storage layers include doped polysilicon.

14. The semiconductor storage device according to claim 7, wherein the first charge storage layers are insulating charge storage layers.

15. The semiconductor storage device according to claim 14, wherein the first charge storage layers include silicon nitride.
